(19) United States
(12) Patent Application Publication
(10) Pub. No.: US 2016/0116776 A1
(43) Pub. Date: Apr. 28, 2016

(54) LIQUID CRYSTAL DISPLAY DEVICE

(71) Applicant: Japan Display Inc., Minato-ku (JP)

(72) Inventors: Hirotaka Hayashi, Tokyo (JP); Masahiro Tada, Tokyo (JP); Kazuhide Mochizuki, Tokyo (JP)

(73) Assignee: Japan Display Inc., Minato-ku (JP)

(21) Appl. No.: 14/883,988

(22) Filed: Oct. 15, 2015

(30) Foreign Application Priority Data
Oct. 28, 2014 (JP) 2014-219216

(51) Int. Cl. G02F 1/1368; G02F 1/1362; G02F 1/1343; H01L 29/786; H01L 27/12

(52) U.S. Cl. CPC G02F 1/1368; H01L 29/78633; H01L 29/78675; H01L 27/124; H01L 27/1222; G02F 1/134336; G02F 1/136209; G02F 2001/13685

(57) ABSTRACT

According to one embodiment, a liquid crystal display device includes a first substrate, a second substrate, and a liquid crystal layer. The first substrate includes a light-shielding layer formed in the shape of a band, a first semiconductor layer, a second semiconductor layer, a gate line, a first pixel electrode and a second pixel electrode. A third region of the first semiconductor layer and a sixth region of the second semiconductor layer are each U-shaped, and each includes a first channel region and a second channel region, which are located opposite to the gate line.

### CROSS-REFERENCE TO RELATED APPLICATIONS

This application is based upon and claims the benefit of priority from Japanese Patent Application No. 2014-219216, filed Oct. 28, 2014, the entire contents of which are incorporated herein by reference.

### FIELD

Embodiments described herein relate generally to a liquid crystal display device.

### BACKGROUND

With respect to liquid crystal display devices, research has been conducted into making pixels smaller to increase resolution. For example, in two dimensions, a plurality of pixels are arranged in a lattice pattern. Furthermore, as a thin-film transistor, a double-gate thin-film transistor using a branch portion of a scanning line is known.

It should be noted that light-shielding layers are provided for thin-film transistors, respectively. To be more specific, the light-shielding layers are located below semiconductor layers of the thin-film transistors and also opposite to the semiconductor layers. The light-shielding layers block backlight which will be directly incident on the semiconductor layers.

### BRIEF DESCRIPTION OF THE DRAWINGS

FIG. 1 is a perspective view schematically showing the configuration of a liquid crystal display device according to an embodiment.

FIG. 2 is a schematic cross-sectional view showing a liquid crystal display panel as shown in FIG. 1.

FIG. 3 is a plan view showing a schematic configuration of an array substrate shown in FIGS. 1 and 2.

FIG. 4 is a schematic configuration view showing each of unit pixels in the liquid crystal display panel.

FIG. 5 is a schematic plan view showing part of the array substrate and part of the unit pixel as shown in FIG. 4.

FIG. 6 is a schematic cross-sectional view of the array substrate which is taken along line VI-VI in FIG. 5.

FIG. 7 is a schematic cross-sectional view of a counter-substrate which is taken along line VII-VII in FIG. 4.

FIG. 8 is a plan view showing a light-shielding layer, first to fourth semiconductor layers and a gate line according to the above embodiment.

FIG. 9 is a schematic configuration view showing four unit pixels in a liquid crystal display panel of a liquid crystal display device according to modification 1 of the above embodiment.

FIG. 10 is a schematic plan view showing part of an array substrate in modification 1 and part of two unit pixels as shown in FIG. 9.

FIG. 11 is a schematic configuration view showing a single unit pixel included in a liquid crystal display panel of a liquid crystal display device according to modification 2 of the above embodiment.

FIG. 12 is a plan view showing part of an array substrate in modification 2, a light-shielding layer, first to third semiconductor layers and a gate line.

FIG. 13 is a schematic plan view showing part of an array substrate in a liquid crystal display device according to modification 3 of the above embodiment, a light-shielding layer, first to third semiconductor layers and a gate line.

### DETAILED DESCRIPTION

In general, according to one embodiment, there is provided a liquid crystal display device comprising: a first substrate; a second substrate located opposite to the first substrate; and a liquid crystal layer held between the first substrate and the second substrate. The first substrate comprises: a light-shielding layer extending in a first direction and formed in a shape of a band; a first semiconductor layer located above the light-shielding layer and including first to third regions, the third region being located between the first and second regions and opposite to the light-shielding layer; a second semiconductor layer located above the light-shielding layer, spaced from the first semiconductor layer in the first direction, and including fourth to sixth regions, the sixth region being located between the fourth and fifth regions and opposite to the light-shielding layer; a gate line located above the first and second semiconductor layers, extending in the first direction and intersecting the third and sixth regions; a first pixel electrode electrically connected to the second region; and a second pixel electrode electrically connected to the fifth region. Each of the third and sixth regions is U-shaped, intersects the gate line in two positions, and includes a first channel region and a second channel region, which are located opposite to the gate line.

An embodiment will be described hereinafter with reference to the accompanying drawings. The disclosure is a mere example, and needless to say, an arbitrary change of gist which can be easily conceived by a person of ordinary skill in the art naturally falls within the inventive scope. To more clarify the explanations, the drawings may pictorially show width, thickness, shape, etc., of each portion as compared with an actual aspect, but they are mere examples and do not restrict the interpretation of the invention. In addition, in the specification and drawings, structural elements having functions identical or similar to functions described with reference to preceding drawings are denoted by the same reference numbers, respectively, as those described with reference to the preceding drawings, and their overlapping detailed descriptions are omitted as appropriate.

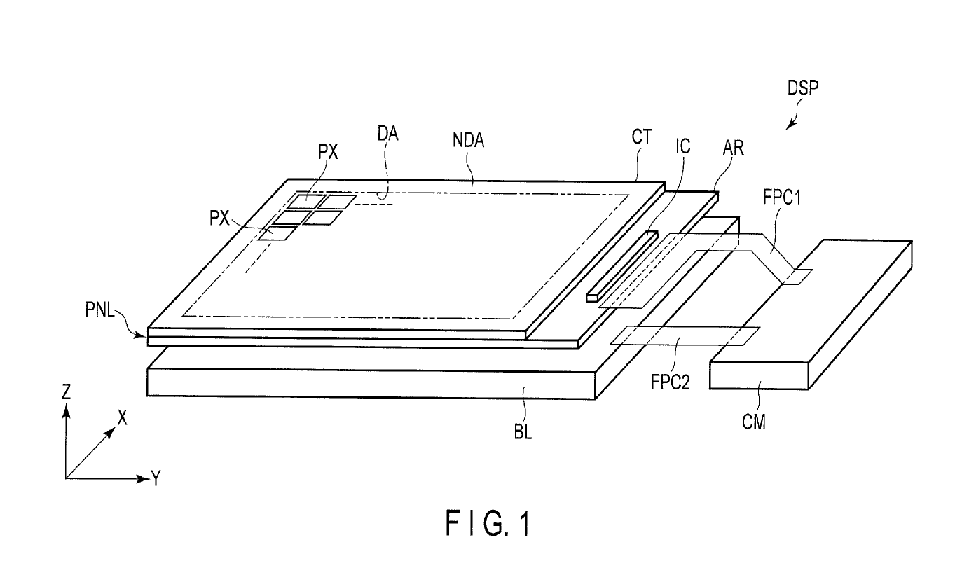

FIG. 1 is a perspective view schematically showing the configuration of a liquid crystal display device according to an embodiment. It should be noted that a first direction X and a second direction Y are perpendicular to each other. Also, a third direction Z is perpendicular to each of the first direction X and the second direction Y.

As shown in FIG. 1, a liquid crystal display device DSP comprises an active-matrix liquid crystal display panel PNL, a driver IC chip IC which drives the liquid crystal display panel PNL, a backlight unit BL which illuminates the liquid crystal display panel PNL, a control module CM, flexible wiring boards FPC1 and FPC2, etc.

The liquid crystal display panel PNL comprises an array substrate and a counter-substrate CT which are each formed in the shape of a flat plate, and which are located opposite to each other, with a predetermined gap interposed between those substrates. In the embodiment, the array substrate AR functions as a first substrate, and the counter-substrate CT functions as a second substrate. The liquid crystal display panel PNL includes a display area DA which displays an image and a non-display area NDA which is formed in the shape of a frame in such a way as to surround the display area DA. The liquid crystal display panel PNL comprises a plurality of pixels PX arranged in a matrix in the display area DA to extend in the first direction X and the second direction Y.

The backlight unit BL is provided on a rear surface of the array substrate AR. As the structure of the backlight unit BL, various structures can be applied. However, a detailed explanation of the structure of the backlight unit BL will be omitted.

The driver IC chip IC is mounted on the array substrate AR. The flexible wiring board FPC1 connects the liquid crystal display panel PNL and the control module CM. The flexible wiring board FPC2 connects the backlight unit BL and the control module CM to each other.

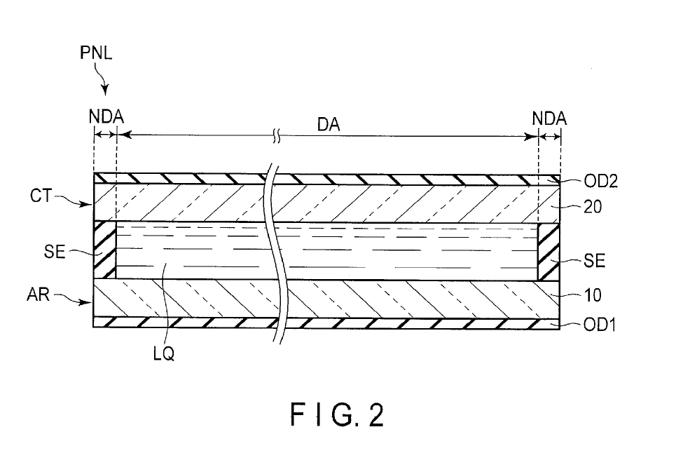

FIG. 2 is a schematic view of the cross section of the liquid crystal display panel.

As shown in FIG. 2, the liquid crystal display panel PNL further comprises a sealing member SE, a liquid crystal layer LQ, a first optical element OD1 and a second optical element OD2. The array substrate AR includes a first insulating substrate 10, and the counter-substrate CT includes a second insulating substrate 20.

The sealing member SE is located in the non-display area NDA, and bonds the array substrate AR and the counter-substrate CT to each other. The liquid crystal layer LQ is held between the array substrate AR and the counter-substrate CT, and provided in space surrounded by the array substrate AR, the counter-substrate CT and the sealing member SE.

The first insulating substrate 10 and the second insulating substrate 20 are formed of a transparent insulating material such as glass or an organic material. The first optical element OD1 and the liquid crystal layer LQ are located on opposite sides of the array substrate AR, respectively; that is, they are located opposite to each other with respect to the array substrate AR. The second optical element OD2 and the liquid crystal layer LQ are located on opposite sides of the counter-substrate CT, respectively; that is, they are located opposite to each other with respect to the counter-substrate CT. The first optical element OD1 and the second optical element OD2 each include a polarizer.

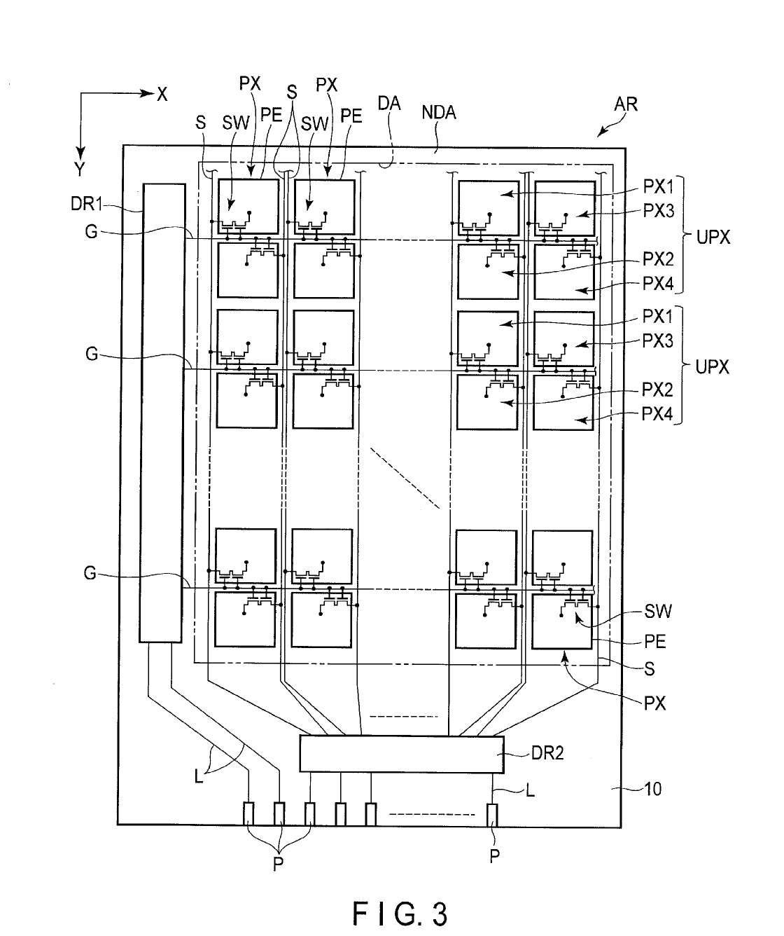

FIG. 3 is a plan view schematically showing the configuration of the array substrate AR.

As shown in FIG. 3, the array substrate AR comprises gate lines G, signal lines S, pixel electrodes PE, switching elements SW, a first drive circuit DR1, a second drive circuit DR2, pads P and lead lines L.

In the display area DA, the gate lines G extend in the first direction X, and arranged and spaced from each other in the second direction Y. In the embodiment, the gate lines G linearly extend in the first direction X. Also, in the display area DA, the signal lines S extend in the second direction Y and intersect the gate lines G; and they are also arranged and spaced from each other in the first direction X. It should be noted that the signal lines S need not always linearly extend; i.e., they may be partially bent or be inclined with respect to the second direction Y. The pixel electrodes PE are located in association with the pixels PX. That is, the pixel electrodes PE are arranged in a matrix in the first direction X and the second direction Y. The switching element SW electrically connects the pixel electrode PE and the signal line S. The switching elements are formed of, for example, thin-film transistors (TFTs). The first drive circuit DR1 and the second drive circuit DR2 are located in the non-display area DNA. The first drive circuit DR1 is electrically connected to portions of the gate lines G which are located in the non-display area NDA. The second drive circuit DR2 is electrically connected to portions of the signal lines S which are located in the non-display area NDA. The pads P are provided at an end portion of the array substrate AR which is one of end portions thereof in the second direction Y. The lead lines L electrically connect, in the non-display area DNA, the first drive circuit DR1 and the pads P, and also the second drive circuit DR2 and the pads P.

The first drive circuit DR1 supplies a control signal to the gate lines G. The second drive circuit DR2 supplies an image signal (for example, a video signal) to the signal lines S. The pads P electrically connect the first drive circuit DR1 and the second drive circuit DR2 to the control module as shown in FIG. 1.

In the embodiment, the pixels PX are classified into four kinds of pixels, i.e., first pixels PX1, second pixels PX2, third pixels PX3 and fourth pixels PX4. To be more specific, a second pixel PX2 is adjacent to a first pixel PX1 in the second direction Y. A third pixel PX3 is adjacent to the first pixel PX1 in the first direction X. The fourth pixel PX4 is adjacent to the second pixel PX2 in the first direction X, and adjacent to the third pixel PX3 in the second direction Y. Those adjacent four pixels PX, i.e., the first pixel PX1, the second pixel PX2, the third pixel PX3 and the fourth pixel PX4, form a unit pixel UPX. A plurality of unit pixels UPX are arranged in a matrix in the first direction X and the second direction Y.

It should be noted that the unit pixels UPX can be translated into picture elements or main pixels. Alternatively, the unit pixels UPX can be translated into pixels. In this case, the above pixels PX can be translated into sub-pixels.

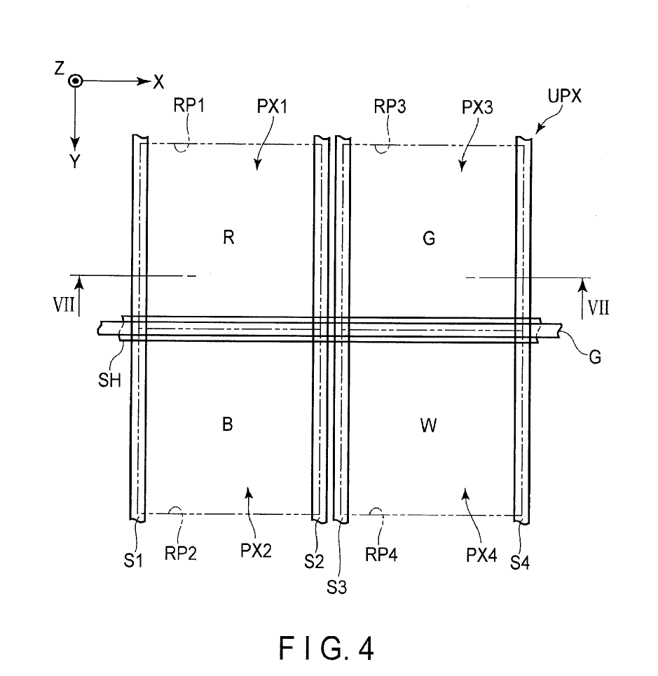

FIG. 4 is a view schematically showing the configuration of a single unit pixel UPX in the liquid crystal display panel PNL. FIG. 4 also shows a light-shielding layer SH, a single gate line G to be used by the unit pixel UPX and four signal lines S1 to S4.

As shown in FIG. 4, the light-shielding layer SH is formed in the shape of a band, and extends in the first direction. The gate line G is located above the light-shielding layer SH. At least part of the gate line G is located opposite to the light-shielding layer SH in the third direction Z. The light-shielding layer SH, as well as the gate line G, is formed without being divided in the display area DA, i.e., it is continuously formed from one end of the display area DA to the other end thereof in the first direction.

The liquid crystal display panel PNL includes a plurality of first to fourth pixel areas RP1 and RP4. To be more specific, each of the unit pixels UPX is associated with first to fourth pixel areas RP1 and RP4.

The first pixel area RP1 is defined by the gate line G, a first signal line S1 and a second signal line S2. Roughly speaking, the first pixel PX1 is located in the first pixel area RP1.

The second pixel area RP2 is defined by the gate line G, the first signal line S1 and the second signal line S2, and located adjacent to the first pixel area RP1, with the gate line G interposed between the second pixel area RP2 and the first pixel area RP1. Roughly speaking, the second pixel PX2 is located in the second pixel area RP2.

The third pixel area RP3 is defined by the gate line G, a third signal line S3 and a fourth signal line S4, and located adjacent to the first pixel area RP1, with the second signal line S2 and the third signal line S3 interposed between the third pixel area RP3 and the first pixel area RP1. Roughly speaking, the third pixel PX3 is located in the third pixel area RP3.

The fourth pixel area RP4 is defined by the gate line G, the third signal line S3 and the fourth signal line S4. The four pixel area RP4 is located adjacent to the third pixel area RP3, with the gate line G interposed between the fourth pixel area RP4 and the third pixel area RP3, and is also located adjacent to the second pixel area RP2, with the second signal line S2 and the third signal line S3 interposed between the fourth pixel area RP4 and the second pixel area PR2.

The first to fourth pixels PX1 to PX4 are respective pixels for different colors. In the embodiment, the first pixel PX1 is a red (R) pixel, the second pixel PX2 is a blue (B) pixel, the third pixel PX3 is a green (G) pixel, and the fourth pixel PX4 is a white (W) pixel.

Furthermore, in the embodiment, the unit pixel UPX is substantially square, and the first to fourth pixels PX1 to PX4 are arranged in a substantially square.

It should be noted that the shape of the unit pixel UPX is not limited to square, and for example, the unit pixel UPX may be rectangular. For example, the first pixel PX1, the second pixel PX2, the third pixel PX3 and the fourth pixel PX4 may be formed as a green (G) pixel, a blue (B) pixel, a red (R) pixel and a white (W) pixel, respectively; the dimension of each of the second pixel PX2 and the fourth pixel PX4 in the second direction Y may be set greater than that of each of the first pixel PX1 and the third pixel PX3 in the second direction Y; and the dimension of each of the third pixel PX3 and the fourth pixel PX4 in the first direction X may be set greater than that of each of the first pixel PX1 and the second pixel PX2 in the first direction X.

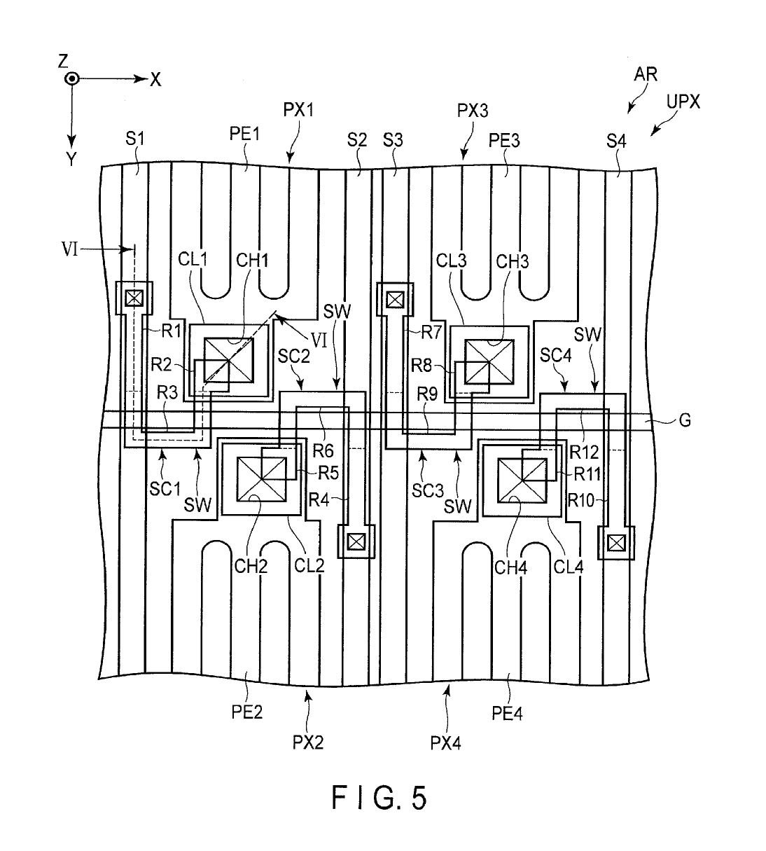

FIG. 5 is a schematic plan view showing part of the array substrate AR, and also showing part of the single unit pixel UPX as shown in FIG. 4.

As shown in FIG. 5, the array substrate AR comprises gate line G, a first signal line S1, a second signal line S2, a third signal line S3, a fourth signal line S4, a first pixel electrode PE1, a second pixel electrode PE2, a third pixel electrode PE3, a fourth pixel electrode PE4, a first semiconductor layer SC1, a second semiconductor layer SC2, a third semiconductor layer SC3, a fourth semiconductor layer SC4, a first conductive layer CL1, a second conductive layer CL2, a third conductive layer CL3 and a fourth conductive layer CL4.

The first semiconductor layer SC1 includes a first region R1 connected to the first signal line S1, a second region R2 and a third region R3. The third region R3 is located between the first region R1 and the second region R2, and intersects a gate line G.

The second semiconductor layer SC2 includes a fourth region R4 connected to the second signal line S2, a fifth region R5 and a sixth region R6. The sixth region R6 is located between the fourth region R4 and the fifth region R5, and intersects the gate line G.

The third semiconductor layer SC3 includes a seventh region R7 connected to the third signal line S3, an eighth region R8 and a ninth region R9. The ninth region R9 is located between the seventh region R7 and the eighth region R8, and intersects the gate line G.

The fourth semiconductor layer SC4 includes a tenth region R10 connected to the fourth signal line S4, an eleventh region R11 and a twelfth region R12. The twelfth region R12 is located between the tenth region R10 and the eleventh region R11, and intersects the gate line G.

In the embodiment, as seen from above, in the X-Y plane, the first pixel area RP1 and the third pixel area RP3 are located on an upper side, the second pixel area RP2 and the fourth pixel area RP4 are located on a lower side, each of the third and ninth regions R3 and R9 is U-shaped, and intersects the gate line G in two positions, and each of the sixth and twelfth regions R6 and R12 is formed in an inverted U-shape, and intersects the gate line G in two positions. Furthermore, the third, sixth, ninth and twelfth regions R3, R6, R9 and R12 have each U-shaped. Thus, as each of the switching elements SW, a double-gate TFT is used. Furthermore, the third, sixth, ninth and twelfth regions R3, R6, R9 and R12 intersect the gate line G at right angles.

The first conductive layer CL1 is located in the first pixel area RP1, and opposite to the second region R2 in the third direction Z, and is electrically connected to the second region R2.

The second conductive layer CL2 is located in the second pixel area RP2, and opposite to the fifth region R5 in the third direction Z, and is electrically connected to the fifth region R5.

The third conductive layer CL3 is located in the third pixel area RP3, and opposite to the eighth region R8 in the third direction Z, and is electrically connected to the eighth region R8.

The fourth conductive layer CL4 is located in the fourth pixel area RP4, and opposite to the eleventh region R11 in the third direction Z, and is electrically connected to the eleventh region R11.

The first pixel electrode PE1 is located in the first pixel area RP1, extends through a first contact hole CH1 located in the first pixel area RP1 to contact the first conductive layer CL1, and is electrically connected to the second region R2.

The second pixel electrode PE2 is located in the second pixel area RP2, extends through a second contact hole CH2 located in the second pixel area RP2 to contact the second conductive layer CL2, and is electrically connected to the fifth region R5.

The third pixel electrode PE3 is located in the third pixel area RP3, and extends through a third contact hole CH3 located in the third pixel area RP3 to contact the third conductive layer CL3, and is electrically connected to the eighth region R8.

The fourth pixel electrode PE4 is located in the fourth pixel area RP4, extends through a contact hole CH4 located in the fourth pixel area RP4 to the fourth conductive layer CL4, and is electrically connected to the eleventh region R11.

It should be noted that the liquid crystal display panel PNL according to the embodiment has a structure adapted for a fringe field switching (FFS) mode applied as a display mode. Thus, the first to fourth pixel electrodes PE1 to PE4 each include a slit.

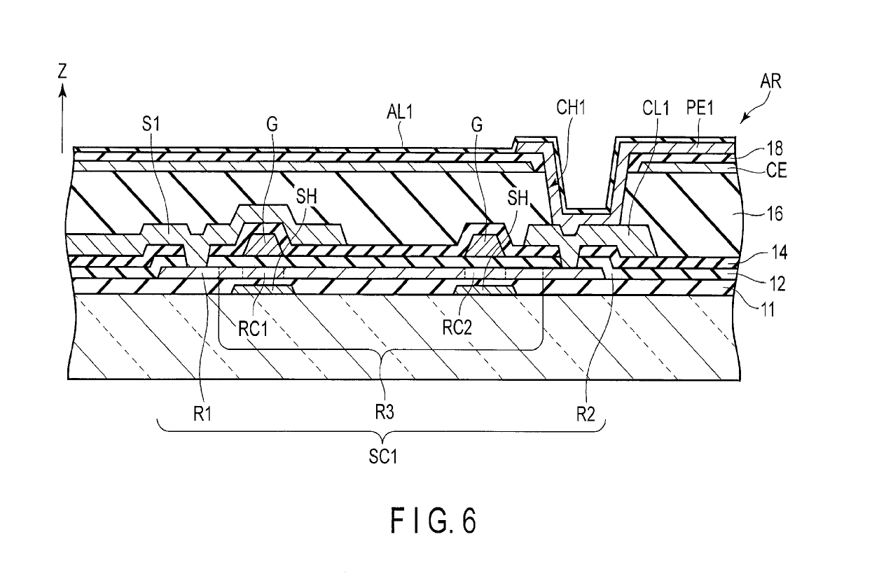

FIG. 6 is a schematic cross-sectional view of the array substrate AR which is taken along line VI-VI in FIG. 5.

As shown in FIG. 6, the light-shielding layer SH is formed on the first insulating substrate 10. The light-shielding layer SH is formed of a material having a light blocking property such as metal. The light-shielding layer SH, which is formed of metal, is in an electrically floating state. An underlayer insulating film 11 is formed on the first insulating film 10 and the light-shielding layer SH. Semiconductor layers such as the first semiconductor layer SC1 are formed on the underlayer insulating substrate 11. The semiconductor layers are located above the light-shielding layer SH. Also, the semiconductor layers are formed of polycrystalline silicon (poly-Si). In the embodiment, the semiconductor layers are formed of low-temperature poly-Si (LIPS).

The third region R3 of the first semiconductor layer SC1 includes a first channel region RC1 and a second channel region RC2 which are located opposite to respective gate line G.

A first insulating film 12 is formed on the underlayer insulating film 11 and the first semiconductor layer SC1 (semiconductor layer). The gate line G is formed on the first insulating film 12 and opposite to the first channel region RC1 and the second channel region RC2. A second insulating film 14 is formed on the gate lines G and the first insulating film 12.

Signal lines such as the first signal line S1 and conductive layers such as the first conductive layer CL1 are formed on the second insulating film 14. The first signal line SI is in contact with the first region R1 of the first semiconductor layer SC1 through a contact hole formed in the first insulating film 12 and the second insulating film 14. The first conductive layer CL1 is in contact with the second region R2 of the first semiconductor layer SC1 through another contact hole formed in the first insulating film 12 and the second insulating film 14.

A third insulating film 16 is formed on the second insulating film 14, the first signal line S1 and the first conductive layer CL1. Also, the third insulating film 16 is located above the gate line G, the first semiconductor layer SC1 (semiconductor layer) and the first signal line S1 (signal line). The third insulating film 16 serves to cover irregularities of the array substrate AR in order for the array substrate AR to have a flat surface. Thus, the third insulating film 16 is formed of an organic material such as acrylic resin, which allows it to be thicker. In the third insulating film 16, a plurality of contact holes such as the first contact hole CH1 are formed. The first contact hole CH1 is located to extend from an upper location than the first conductive layer CL1 to reach and expose the first conductive layer CL1.

A common electrode CE is formed on the third insulating film 16. The common electrode CE includes a plurality of opening portions which surround the contact holes such as the first contact hole CH1. A fourth insulating film 18 is formed on the third insulating film 16 and the common electrode CE. The first insulating film 12, the second insulating film 14 and the fourth insulating film 18 are formed of an inorganic material, for example, silicon nitride (SiN) or silicon oxide (SiO).

Pixel electrodes such as the first pixel electrode PE1 are formed on the fourth insulating film 18. Also, the pixel electrodes such as the first pixel electrode PE1 are located above the third insulating film 16. The first pixel electrode PE1 is in contact with the first conductive layer CL1 through the first contact hole CH1. It should be noted that the first pixel electrode PE1 extends through not only the first contact hole CH1, but another contact hole which is formed in the fourth insulating film 18 and located opposite to the first contact hole CH1. The first pixel electrode PE1 is located opposite to the common electrode CE in the third direction Z. The common electrode CE and the first pixel electrode PE1 (pixel electrode) are formed of a transparent conductive material such as indium zinc oxide (IZO) or indium tin oxide (ITO).

An alignment film AL is formed on the fourth insulating film 18 and the pixel electrodes PE. The alignment film AL1 is formed of, for example, a material exhibiting a horizontal alignment property. The alignment film AL1 is a film subjected to alignment treatment.

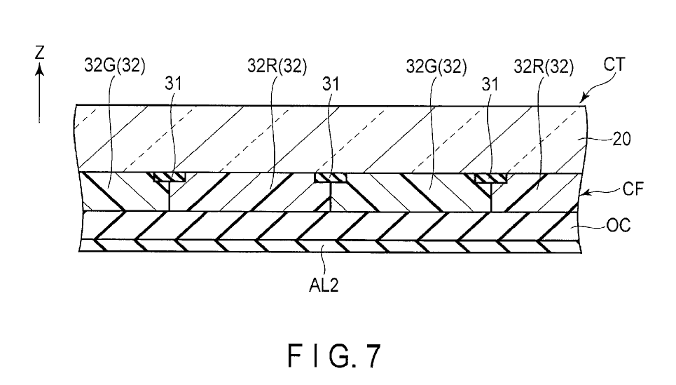

FIG. 7 is a schematic cross-sectional view of the counter-substrate CT which is taken along line VII-VII in FIG. 4. As shown in FIG. 7, the counter-substrate CT comprises the second insulating substrate 20, a color filter CF, an overcoat layer OC and an alignment film AL2.

The color filter CF includes the light-shielding layer 31. The light-shielding layer 31 is formed on the second insulating substrate 20. The light-shielding layer 31 is formed of a material having a low light transmittance and a low reflectivity. The light-shielding layer 31 is formed to have portions arranged at least in the manner of stripes, extend in the first direction X, and located opposite to the gate lines G. In the embodiment, the light-shielding layer 31 is formed in the shape of a lattice, and located opposite to the gate lines G and also to the signal lines S.

The color filter CF includes colored layers 32 having different colors (or transparent layers 32). In the embodiment, the color filter CF includes a plurality of colored layers, i.e., red layers 32 (32R) provided in regions corresponding to the first pixels PX1, blue layers 32 provided in regions corresponding to the second pixels PX2, green layers 32 (32G) provided in regions corresponding to the third pixels PX3, and transparent layers 32 provided in regions corresponding to the fourth pixels PX4.

The red layers 32R are formed of red-colored resin. The blue layers 32 are formed of blue-colored resin. The green layers 32G are formed of green-colored resin. The transparent layers 32 are formed of transparent resin.

It should be noted that the transparent layers 32 may be faintly colored to such an extent not to adversely affect a displayed image. Alternatively, the color filter 30 can be formed without the transparent layers 32.

The overcoat layer OC is formed of a transparent resin material and provided on the color filter CF. The overcoat layer OC can reduce the irregularities of a surface of the counter-substrate CT. It suffices that the overcoat layer OC is designed as occasion demands.

The alignment film AL2 is formed on the overcoat layer OC. The alignment film AL2 is formed of a material exhibiting a horizontal alignment property. The alignment film AL2 is a film subjected to alignment treatment.

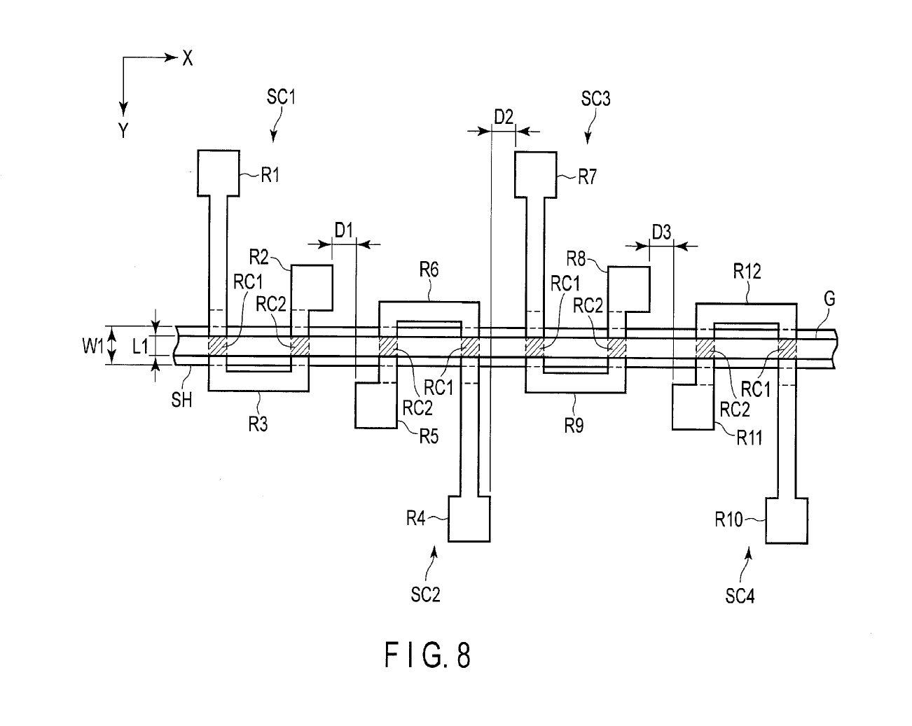

FIG. 8 is a plan view showing the light-shielding layer SH, the first to fourth semiconductor layers SC1 to SC4 and the gate line G.

As shown in FIG. 8, the first to fourth semiconductor layers SC1 to SC4, that is, the third region R3, the sixth region R6, the ninth region R9 and the twelfth region R12, each include a first channel region RC1 and a second channel region RC2. In the embodiment, W1 is greater than L1 as shown in FIG. 8, where W1 is the width of the light-shielding layer SH in the second direction Y, and L1 is the length (first channel length) of each of the first channel region RC1 and the length (second channel length) of the second channel region RC2 in the second direction Y.

In the embodiment, the first channel regions RC1 and the second channel regions RC2 are completely located opposite to the light-shielding layer SH.

The first to fourth semiconductor layers SC1 to SC4 are arranged and spaced from each other by distances D1 to D3 in the first direction X. The distances D1 to D3 are each equal to or greater than a specific value. The distance D1 is the distance from one of ends of the first semiconductor layer SC1 to one of ends of the second semiconductor layer SC2 in the first direction X, the above one end of the first semiconductor layer SC1 being closer to the second semiconductor layer SC2 than the other end of the first semiconductor layer SC1, the above one end of the second semiconductor layer SC2 being closer to the first semiconductor layer SC1 than the other end of the second semiconductor layer SC2. The distance D2 is the distance from the above other end of the second semiconductor layer SC2 to one of ends of the third semiconductor layer SC3 in the first direction X, the above one end of the third semiconductor layer SC3 being closer to the second semiconductor layer SC2 than the other end of the third semiconductor layer SC3. The distance D3 is the distance from the above other end of the third semiconductor layer SC3 to one of ends of the fourth semiconductor layer SC4 in the first direction X, the above one end of the fourth semiconductor layer SC4 being closer to the third semiconductor layer SC3 than the other end of the fourth semiconductor layer SC4.

In the embodiment, the liquid crystal display device having the above structure comprises the array substrate AR, the counter-substrate CT and the liquid crystal layer LQ. The array substrate AR comprises the light-shielding layer SH, the semiconductor layers SC (SC1 to SC4), the gate lines G and the pixel electrodes PE (PE1 to PE4).

The semiconductor layers SC are located above the light-shielding layer SH. The first channel regions RC1 and second channel regions RC2 of the semiconductor layers SC are completely located opposite to the light-shielding layer SH. The light-shielding layer can block backlight which can be directly incident on the semiconductor layers. Furthermore, as each of the switching elements SW, a double-gate TFT is used. This can restrict current leakage which may occur in the first and second channel regions RC1 and RC2 upon emission of light to those channel regions.

The above single light-shielding layer SH continuously extends from one of ends of the display area DA to the other in the first direction X, and is formed in the shape of a band. The single light-shielding layer SH is configured to block backlight which can be emitted to the first and second channel regions RC1 and RC2 of all the semiconductor layers SC arranged in the first direction. The light-shielding layer SH is single, that is, in the embodiment, it is not set that light-shielding layers are provided independent of each other and for the pixels PX, respectively. Therefore, the light-shielding layer SH can be formed without a limitation on processing which would be put in the case where light-shielding layers are provided independent of each other and for the pixels PX, respectively. It should be noted that the limitation on the processing is a limitation in which in processing of forming a plurality of light-shielding layers SH, each of the distances between them must be set to a predetermined value or more.

In the embodiment, although the distances D1 to D3 between the semiconductor layers SC are limited, a plurality of light-shielding layers are not provided, and thus there is no limitation on the distances between the light-shielding layers. Thus, the pitch of the pixels PX in the first direction X can be reduced because of no limitation on the distances between light-shielding layers. Furthermore, the pixels PX can be made smaller, thus contributing to the achievement of a higher resolution.

The gate lines G extend in the first direction. Also, the gate lines G are formed so as not to project from their side edges in the second direction Y. This can thus contribute to the improvement of the aperture ratios of the pixels PX, as compared with the case of using gate lines provided with projection portions.

By virtue of the above structural features, according to the embodiment, it is possible to obtain a liquid crystal display device which can achieve a higher resolution.

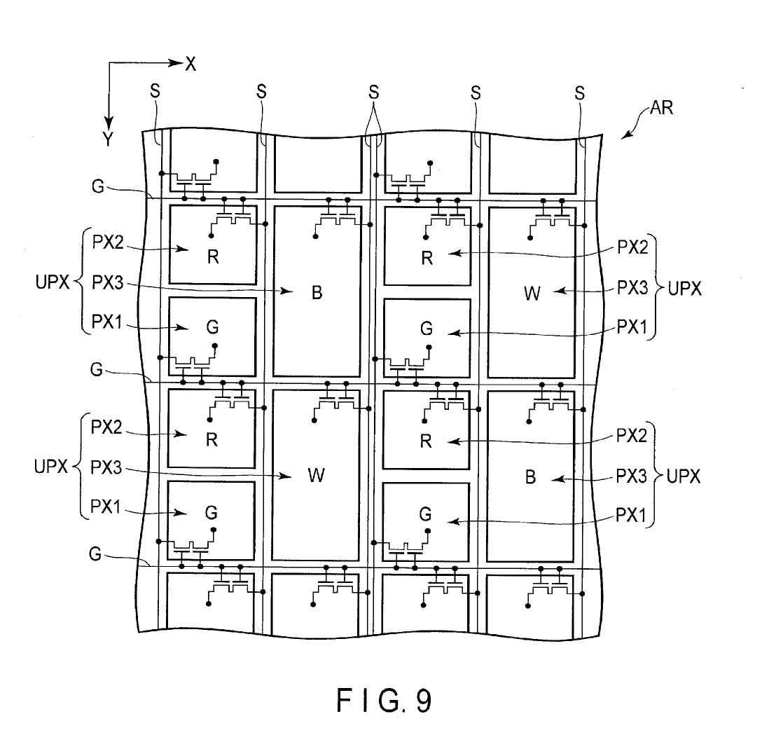

Next, a liquid crystal display device according to modification 1 of the above embodiment will be described. The liquid crystal display device according to modification 1 is different from that according to the above embodiment with respect to the configuration of unit pixels UPX, the relationship in connection between the unit pixels UPX and gate lines G and the relationship in connection between the unit pixels UPX and signal lines S. FIG. 9 is a schematic configuration view showing each of four unit pixels UPX in a liquid crystal display panel PNL of the liquid crystal display device according to modification 1.

As shown in FIG. 9, a plurality of unit pixels UPX are arranged in a matrix in the first direction X and the second direction Y. Each of the unit pixels UPX comprises a first pixel PX1, a second pixel PX2 which is located adjacent to the first pixel PX1 in the second direction Y, and a third pixel PX3 which is located adjacent to both the first pixel PX1 and the second pixel PX2 in the first direction X. In the X-Y plane, the sizes of the first to third pixels PX1 to PX3 (first to third pixel electrodes PE1 to PE3) are not specifically limited. For example, the size of the third pixel PX3 (the third pixel electrode PE3) may be equivalent to the total size of the first pixel PX1 (the first pixel electrode PE1) and the second pixel PX2 (the second pixel electrode PE2).

In modification 1, the first pixel PX1 is a green (G) pixel, the second pixel PX2 is a red (R) pixel, and the third pixel PX3 is a blue (B) or white (W) pixel. Colored layers and transparent layers of the color filter CF are arranged in association with the first to third pixels PX1 to PX3. Unit pixels UPX including third pixels PX3 provided as blue pixels and unit pixels UPX including third pixels PX3 provided as white pixels are arranged in a checkered pattern.

A plurality of third pixels PX3 arranged in the second direction Y share a single signal line S (a third signal line S3 to be described later).

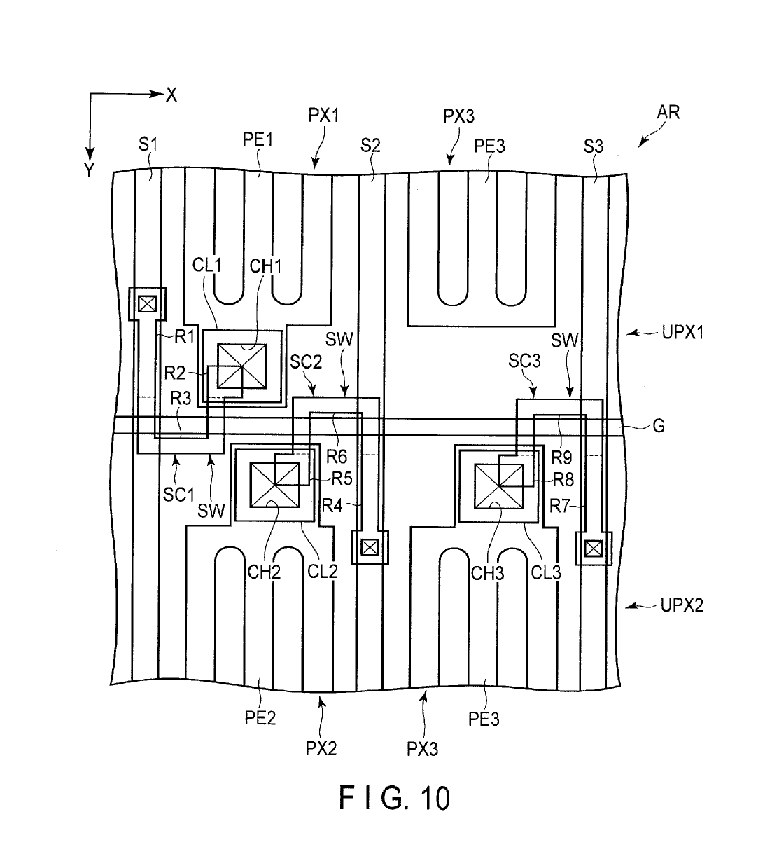

FIG. 10 is a schematic plan view showing part of an array substrate AR in modification 1, and also showing part of two unit pixels UPX as shown in FIG. 9.

As shown in FIG. 10, of the unit pixels UPX, two unit pixels UPX which are located between first and third signal lines S1 and S3 and adjacent to each other, with a gate line G interposed between those two unit pixels UPX, will be referred to as a first unit pixel UPX1 and a second unit pixel UPX2, respectively. To the first unit pixel UPX1 and the second unit pixel UPX2, three signal lines, i.e., the first signal line S1, the second signal line S2 and the third signal line S3, are connected.

First pixel PX1 of the first unit pixel UPX1 includes a first semiconductor layer SC1 and a first pixel electrode PE1. Second pixel PX2 of the second unit pixel UPX2 includes a second semiconductor layer SC2 and a second pixel electrode PE2. Third pixel PX3 of the second unit pixel UPX2 includes a third semiconductor layer SC3 and a third pixel electrode PE3.

First pixel PX1 of the first unit pixel UPX1, second pixel PX2 of the second unit pixel UPX2 and one of third pixel PX3 of the first unit pixel UPX1 and third pixel PX3 of the second unit pixel UPX2 share one gate line G. In modification 1, first pixel PX1 of the first unit pixel UPX1, second pixel PX2 of the second unit pixel UPX2 and third pixel PX3 of the second unit pixel UPX2 share one gate line G.

Also, in modification 1, the light-shielding layer SH is formed to continuously extend from one of ends of the display area DA to the other in the first direction.

By virtue of the above structure, modification 1 can also obtain the same advantage as the above embodiment. In addition, the areas of blue pixels having a low luminosity factor may be made larger than those of red pixels or those of green pixels, thereby improving the display quality of the liquid crystal display device.

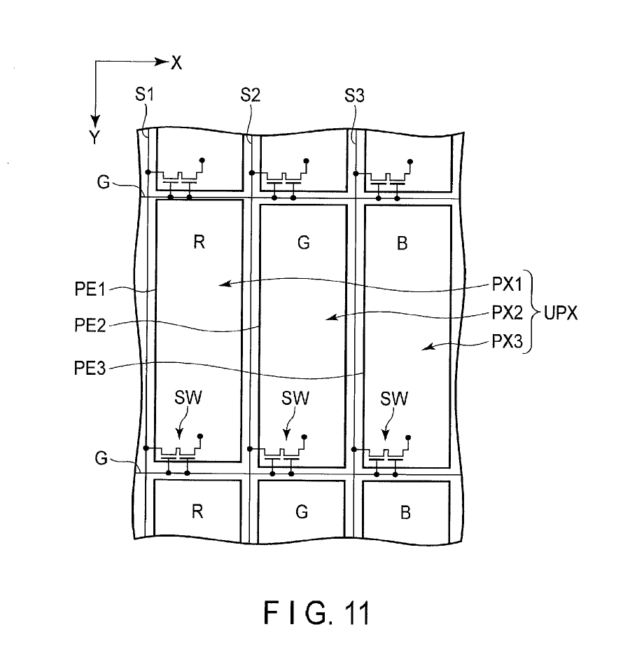

Next, a liquid crystal display device according to modification 2 of the above embodiment will be described. The liquid crystal display device according to modification 2 is different from that according to the above embodiment with respect to the configuration of unit pixels UPX, the relationship in connection between the unit pixels UPX and gate lines G and the relationship in connection between the unit pixels UPX and signal lines S. FIG. 11 is a schematic configuration view showing a single unit pixel UPX in a liquid crystal display panel PNL of the liquid crystal display device according to modification 2.

As shown in FIG. 11, a plurality of unit pixels UPX are arranged in a matrix in the first direction X and the second direction Y. Each of the unit pixels UPX comprises a first pixel PX1, a second PX2 and a third pixel PX3 which are sequentially arranged in the first direction X. In the X-Y plane, the sizes of the first to third pixels PX1 to PX3 (first to third pixel electrodes PE1 to PE3) are not specifically limited. For example, the first to third pixels PX1 to PX3 (first to third pixel electrodes PE1 to PE3) may have the same size.

In modification 2, the first pixel PX1 is a red (R) pixel, the second pixel PX2 is a green (G) pixel, and the third pixel PX3 is a blue (B) pixel. Colored layers of the color filter CF are arranged in association with the first to third pixels PX1 to PX3. It should be noted that in modification 2, the color filter CF is formed with no transparent layer.

The first to third pixels PX1 to PX3 of each unit pixel UPX share a single gate line G. The first pixel PX1 uses a first signal line S1, the second pixel PX2 uses a second signal line S2, and the third pixel PX3 uses a third signal line S3.

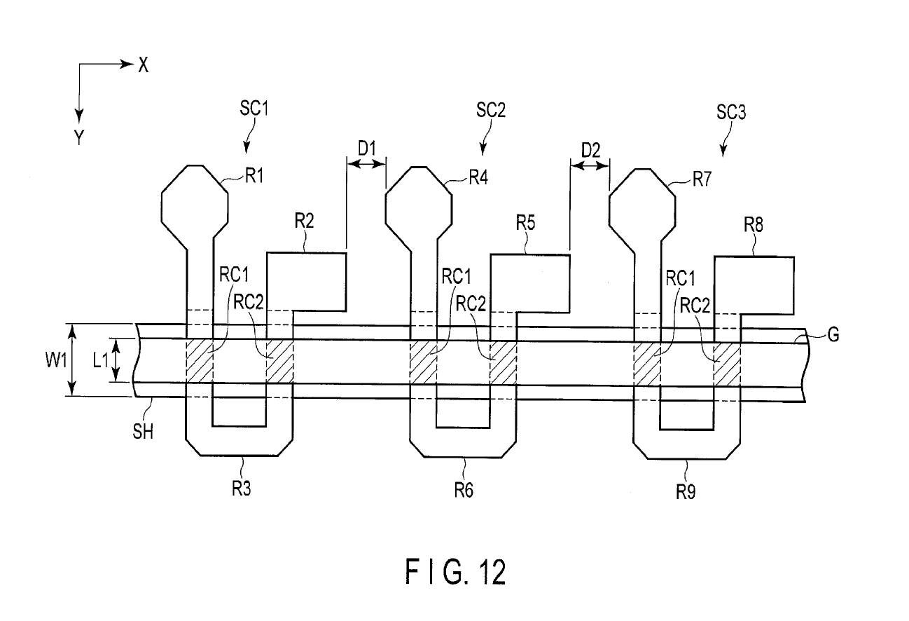

FIG. 12 is a schematic view showing part of an array substrate AR in modification 2, a light-shielding layer SH, first to third semiconductor layers SC1 to SC3 and a gate line G.

As shown in FIG. 12, the first to third semiconductor layers SC1 to SC3, that is, a third region R3, a sixth region R6 and a ninth region R9, each includes a first channel region RC1 and a second channel region RC2. In modification 2, the width W1 of the light-shielding layer SH in the second direction Y is greater than each of the length L1 of the first channel region RC1 and the length L1 of the second channel region RC2 in the second direction Y. In modification 2, the first channel regions RC1 and the second channel regions RC2 are completely located opposite to the light-shielding layer SH.

Furthermore, the first to fourth semiconductor layers SC1 to SC3 are arranged and spaced from each other by distances D1 and D2 in the first direction X. The distances D1 and D2 are each equal to or greater than a specific value.

In modification 2, as seen from above, in the X-Y plane, the pixel electrodes PE (2E1 to 2E3) for use by the first to third pixels PX1 to PX3 are located on an upper side, the gate line G for use by those pixels is located on a lower side, and each of the third, sixth and ninth regions R3, R6 and R9 is U-shaped, and intersects the gate line G in two positions. Thus, as each of the switching elements SW, a double-gate TFT is used. Furthermore, the third, sixth and ninth R3, R6 and R9 intersect the gate line G at right angles.

Also, in modification 2, the light-shielding layer SH is formed to continuously extend from one of ends of a display area DA to the other in the first direction.

By virtue of the above structure, modification 2 can also obtain the same advantage as the above embodiment.

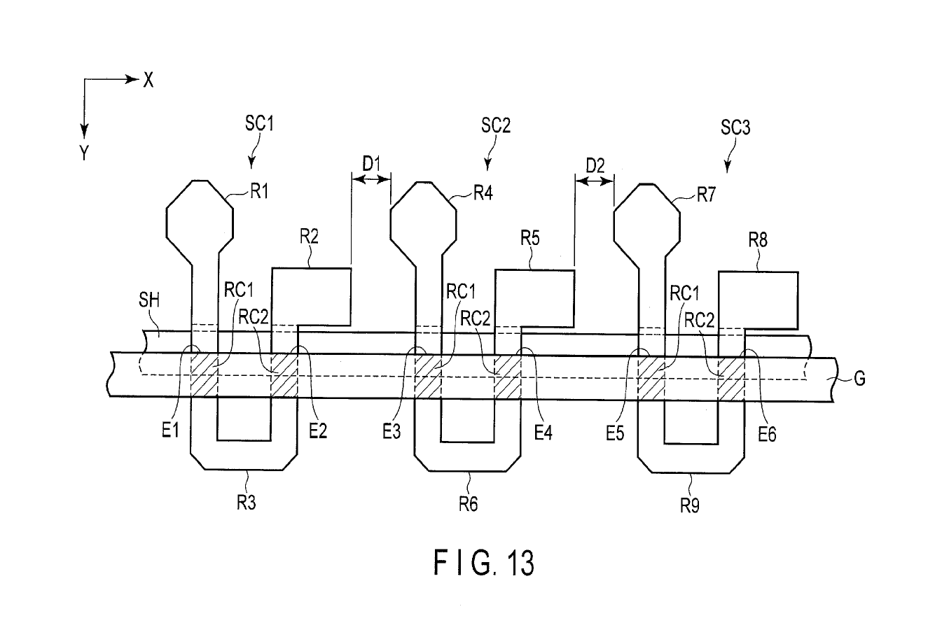

Next, a liquid crystal display device according to modification 3 of the above embodiment will be described. The liquid crystal display device according to modification 3 is different from that according to modification 2 with respect to the positional relationship between a light-shielding layer SH and channel regions (RC1 and RC2). FIG. 13 is a plan view showing part of an array substrate AR in the liquid crystal display device in modification 3, and also showing the light-shielding layer SH, first to third semiconductor layers SC1 to SC3 and a gate line G.

As shown in FIG. 13, a first channel region RC1 of the first semiconductor layer SC1 is located between a first region R1 and a second channel region RC2 of the first semiconductor layer SC1. A first channel region RC1 of the second semiconductor layer SC2 is located between a fourth region R4 and a second channel region RC2 of the second semiconductor layer SC2. A first channel region RC1 of the third semiconductor layer SC3 is located between a seventh region R7 and a second channel region RC2 of the third semiconductor layer SC3.

The light-shielding layer SH is formed to have such a width as to extend over ends E1 to E6 of the channel regions in the second direction Y. The end E1 is one of ends of the first channel region RC1 of the first semiconductor layer SC1, which is closer to the first region R1. The end E2 is one of ends of the second channel region RC2 of the first semiconductor layer SC1, which is closer to a second region R2. The end E3 is one of ends of the first channel region RC1 of the second semiconductor layer SC2, which is closer to the fourth region R4. The end E4 is one of ends of the second channel region RC2 of the second semiconductor layer SC2, which is closer to a fifth region R5. The end E5 is one of ends of the first channel region RC1 of the third semiconductor layer SC3, which is closer to the seventh region R7. The end E6 is one of ends of the second channel region RC2 of the third semiconductor layer SC3, which is closer to an eighth region R8.

Also, in modification 3, the light-shielding layer SH is formed to continuously extend from one of ends of a display area DA to the other in the first direction.

In addition, the light-shielding layer SH is provided such that each of the first channel regions RC1 and the second channel regions RC2 is not entirely opposite to the light-shielding layer SH, i.e., such that it is partially opposite to the light-shielding layer SH; however, the light-shielding layer SH is formed to have such a width as to extend over the ends E1 to E6 of the channel regions in the second direction Y. This structural feature can thus restrict current leakage which may occur at the channel regions when light is radiated onto the vicinity of the ends (E1 to E6) of the channel regions. It should be noted that the above current leakage easily occurs when light is radiated onto the vicinity of the ends (E1 to E6) of the channel regions.

By virtue of the above structure, modification 3 can also obtain the same advantage as the above embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the shape of each of the pixels PX and colors of the color filter CF which are associated with the pixels PX are not limited to those referred to above with respect to the above embodiment and the modifications. They can be variously changed.

Furthermore, the above embodiment is not limited to the above liquid crystal display devices; that is, it can be applied to various liquid crystal display devices. Needless to say, the above embodiment can be applied to middle or small display devices and large display devices without particular limitation.

For example, the liquid crystal display panel PNL in the above embodiment has a structure adapted for the FFS mode used as a display mode; however, it may have a structure adapted for another display mode. For example, the liquid crystal display panel PNL may have a structure adapted for an in-plane switching (IPS) mode such as an FFS mode, which primarily utilizes a lateral electric field substantially parallel to a main surface of a substrate. In a display mode utilizing a lateral electric field, it is possible to apply a structure including, for example, an array substrate AR provided with pixel electrodes PE and a common electrode CE. Alternatively, a liquid crystal display panel PNL may have a structure adapted for a mode primarily utilizing a longitudinal electric field substantially perpendicular to the main surface of the substrate, such as a twisted nematic (TN) mode, an optically compensated bend (OCB) mode or a vertical aligned (VA) mode. In the display mode utilizing the longitudinal electric field, for example, it is possible to apply a structure including an array substrate AR provided with pixel electrodes PE and a counter-substrate CT provided with a common electrode CE. It should be noted that the above main surface of the substrate is a surface parallel to the X-Y plane defined in the first direction X and the second direction Y which intersect each other.

What is claimed is:

1. A liquid crystal display device comprising a first substrate, a second substrate located opposite to the first substrate and a liquid crystal display held between the first and second substrates,
wherein the first substrate comprises:
a light-shielding layer extending in a first direction and formed in a shape of a band;
a first semiconductor layer located above the light-shielding layer and including first to third regions, the third region being located between the first and second regions and opposite to the light-shielding layer;
a second semiconductor layer located above the light-shielding layer, spaced from the first semiconductor layer in the first direction, and including fourth to sixth regions, the sixth region being located between the fourth and fifth regions and opposite to the light-shielding layer;
a gate line located above the first and second semiconductor layers, extending in the first direction and intersecting the third and sixth regions;
a first pixel electrode electrically connected to the second region; and
a second pixel electrode electrically connected to the fifth region, and
wherein each of the third and sixth regions is U-shaped, intersects the gate line in two positions, and includes a first channel region and a second channel region, which are located opposite to the gate line.

2. The liquid crystal display device of claim 1, wherein
the first and second pixel electrodes are located adjacent to each other, with the gate line interposed between the first and second pixel electrodes,
as seen in a plan view in which the first pixel electrode is located on an upper side, and the second pixel electrode is located on a lower side, the third region is U-shaped, and the sixth region is formed in an inverted U-shape.

3. The liquid crystal display device of claim 2, wherein the third region and the sixth region intersect the gate line at right angles.

4. The liquid crystal display device of claim 1, wherein the third region and the sixth region intersect the gate line at right angles.

5. The liquid crystal display device of claim 1, wherein the first semiconductor layer and the second semiconductor layer are formed of polycrystalline silicon.

6. The liquid crystal display device of claim 1, wherein
a width of the light-shielding layer in a second direction perpendicular to the first direction is greater than a length of the first channel region and that of the second channel region in the second direction,
the first channel region and the second channel region are entirely located opposite to the light-shielding layer.

7. The liquid crystal display device of claim 1, wherein
the first channel region of the first semiconductor layer is located between the first region and the second channel region of the first semiconductor layer,
the first channel region of the second semiconductor layer is located between the fourth region and the second channel region of the second semiconductor layer, and
the light-shielding layer is formed to have a width to extend in a second direction perpendicular to the first direction, over one of ends of the first channel region of the first semiconductor layer which is closer to the first region, one of ends of the second channel region of the first semiconductor layer which is closer to the second region, one of ends of the first channel region of the second semiconductor layer which is closer to the fourth region, and one of ends of the second channel region of the second semiconductor layer which is closer to the fifth region.

8. The liquid crystal display device of claim 1, wherein the first substrate further comprises:
a plurality of unit pixels arranged in a matrix in the first direction and a second direction perpendicular to the first direction, and each comprising first to fourth pixels, the second pixel being located adjacent to the first pixel in the second direction, the third pixel being located adjacent to the first pixel in the first direction, the fourth pixel being located adjacent to the second pixel in the first direction and adjacent to the third pixel in the second direction;
a third semiconductor layer located above the light-shielding layer, spaced from the second semiconductor layer in the first direction, and including seventh to ninth regions, the ninth region being located between the seventh and eighth regions and opposite to the light-shielding layer;
a fourth semiconductor layer located above the light-shielding layer, spaced from the third semiconductor layer in the first direction, and including tenth to twelfth regions, the twelfth region being located between the tenth and eleventh regions and opposite to the light-shielding layer;
a third pixel electrode electrically connected to the eighth region; and
a fourth pixel electrode electrically connected to the eleventh region,
wherein the gate line is also located above the third and fourth semiconductor layers, and intersects the ninth and twelfth regions, and
wherein the first pixel includes the first semiconductor layer and the first pixel electrode, the second pixel includes the second semiconductor layer and the second pixel electrode, the third pixel includes the third semiconductor layer and the third pixel electrode, and the fourth pixel includes the fourth semiconductor layer and the fourth pixel electrode.

9. The liquid crystal display device of claim 1, wherein the first substrate further comprises:
a plurality of unit pixels arranged in a matrix in the first direction and a second direction perpendicular to the first direction, and each comprising first to third pixels, the second pixel being located adjacent to the first pixel in the second direction, the third pixel being located to both the first and second pixels in the first direction;
a third semiconductor layer located above the light-shielding layer, spaced from the second semiconductor layer in the first direction, and including seventh to ninth regions, the ninth region being located between the seventh and eighth regions and opposite to the light-shielding layer; and
a third pixel electrode electrically connected to the eighth region,
wherein the gate line is also located above the third semiconductor layer, and intersects the ninth region, and
wherein in first and second unit pixels of the unit pixels, which are located adjacent to each other, with the gate line interposed between the first and second unit pixels, the first pixel of the first unit pixel includes the first semiconductor layer and the first pixel electrode, the second pixel of the second unit pixel includes the second semiconductor layer and the second pixel electrode, and one of the third pixel of the first unit pixel and the third pixel of the second unit pixel includes the third semiconductor layer and the third pixel electrode.
